(19) United States
(12) Patent Application Publication
(10) Pub. No.: US 2010/0309038 A1
(43) Pub. Date: Dec. 9, 2010

(54) ANALOG TO DIGITAL CONVERTER

(75) Inventor: Chih-Haur Huang, Tainan County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: HIMAX MEDIA SOLUTIONS, INC., Tainan County (TW)

(21) Appl. No.: 12/479,901

(22) Filed: Jun. 8, 2009

(51) Int. Cl. H03M 1/38; H03M 1/12; H03M 1/00

(52) U.S. Cl. 341/156; 341/161; 341/122

(57) ABSTRACT

An analog to digital converter is provided. The converter comprises a first stage, an adjustment unit and a digital error correction logic. The first stage has a first sensing range and receives a first voltage to generate a first digital code. The adjustment unit adjusts the first sensing range of the first stage. The digital error correction logic receives and corrects the first digital code to generate a digital code corresponding to the first voltage.

### BACKGROUND OF THE INVENTION

1. Field of the Invention

The present invention relates to an analog to digital converter, and more particularly to an analog to digital converter having high linearity.

2. Description of the Related Art

Consumers increasingly rely on digital resources provided by electronic devices such as cellular telephones, digital cameras, or portable and handheld digital electronic devices. The electronic devices process and/or produce both digital and analog signals. Meanwhile, the demand for faster transmission of digital data is increasing, along with increasing demand for applications such as wireless networks, downloadable digital music devices, digital movie devices, and others.

Electronic devices require the receipt of analog signals, which are then converted to digital signals, referred to as analog to digital (A/D) conversion. The electronic devices include appropriate circuitry to perform the A/D conversion to perform digital signal processing.

The pipelined architecture for Analog-to-Digital Conversion (ADC) rely on the concept of simultaneous data sub-conversion in multiple stages in order to progressively refine the digital representation of an analog signal. There are two fundamental approaches to pipelined ADC: a switched-capacitor, and a switched-current approach. In both of the approaches, the ADC apparatus is negatively influenced when components employed during stages of the pipelined ADC are mismatched.

FIG. 1 is a schematic diagram showing an analog-to-digital conversion error in a conventional analog to digital converter. The vertical axis is the DNL (differential nonlinearity) value which is the difference between an actual output digital value and an ideal output digital value. The horizontal axis is the ideal output digital value. In FIG. 3, two peaks of the DNL value occur at the ideal output digital values 96 and 160. Thus, the output digital value is 97 and 161, not 96 and 160. The DNL peaks are generated due to the capacitor mismatch, operation amplifier error or settling error in the analog to digital converter. Thus, performance and linearity of the analog to digital converter is decreased.

### BRIEF SUMMARY OF THE INVENTION

An embodiment of an analog to digital converter is provided. The converter comprises a first stage, an adjustment unit and a digital error correction logic. The first stage has a first sensing range and receives a first voltage to generate a first digital code. The adjustment unit adjusts the first sensing range of the first stage. The digital error correction logic receives and corrects the first digital code to generate a digital code corresponding to the first voltage.

An embodiment of a video device is provided. The device comprises an analog to digital converter and a display unit. The analog to digital converter converts a first analog signal to a digital signal. The display unit receives the digital signal to show a corresponding image. The converter further comprises a first stage, an adjustment unit and a digital error correction logic. The first stage has a first sensing range and receives a first analog signal to generate a first digital signal. The adjustment unit adjusts the first sensing range of the first stage. The digital error correction logic receives and corrects the first digital signal to generate the digital signal corresponding to the first voltage.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a schematic diagram showing an analog-to-digital conversion error in a conventional analog to digital converter.

FIG. 2 is a block diagram of an embodiment of an analog to digital converter according to the invention.

FIG. 3 is a block diagram of another embodiment of an analog to digital converter according to the invention.

FIG. 4 is a block diagram of an embodiment of the first stage in FIG. 2 according to the invention.

FIG. 5 is a schematic diagram showing the distribution of the DNL values of an embodiment of an analog to digital converter according to the invention.

FIG. 6 is a schematic diagram of an embodiment of a video device according to the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

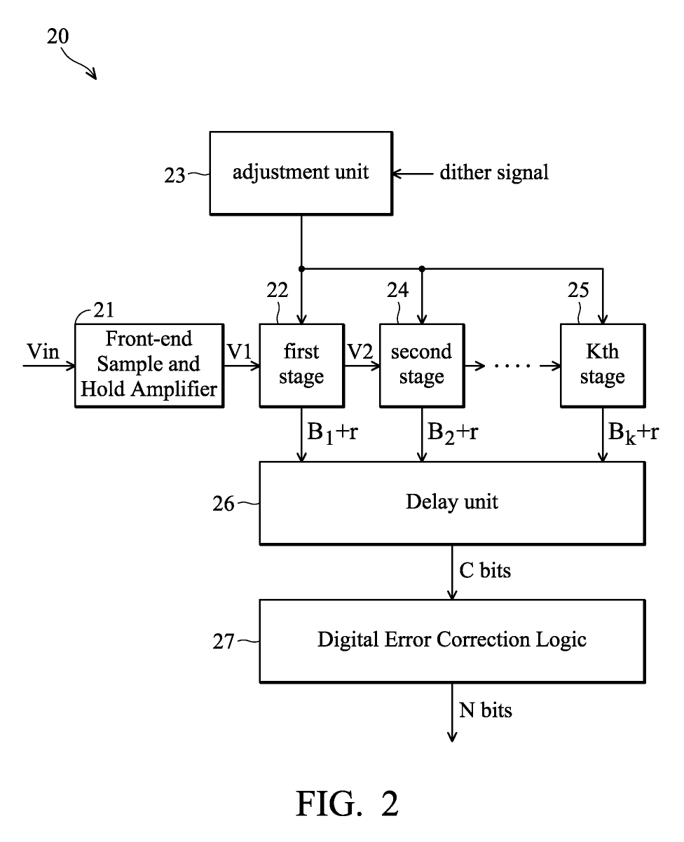

FIG. 2 is a block diagram of an embodiment of an analog to digital converter according to the invention. The analog to digital converter 20 comprises a front-end sample and hold amplifier 21, a first stage 22, an adjustment unit 23, a second stage 24, a k^{th} stage 25, a delay unit 26 and a digital error correction logic 27. In this embodiment, the operation of each stage, such as the first stage 22, the second stage 24, or the k^{th} stage 25, is substantially the same, and the last stage, the k^{th} stage 25, is a flash analog to digital converter.

By utilizing the adjustment unit 23, the linearity of the analog to digital converter 20 can be improved. In FIG. 2, the sensing ranges of the first stage 22, the second stage 24, or the k^{th} stage 25 are adjusted by the same adjustment value, however, the invention is not limited thereto. Those skilled in the art may adjust each stage by different adjustment values, and the linearity of the analog to digital converter 20 can be improved more efficiently.

The front-end sample and hold amplifier 21 receives, samples and amplifies the input voltage Vin to generate a first voltage V1. It is noted that the front-end sample and hold amplifier 21 may not amplify the voltage Vin, and only sample the input voltage Vin, and the amplitude of the input voltage Vin is the same as the first voltage V1. The first stage 22 receives the first voltage V1 to generate a second voltage V2 and a first digital code. The first digital code is shown as B₁+r, wherein r indicates the error part or redundant part of the analog-to-digital conversion. In this embodiment, B₁ may be one bit value or a plurality of bit values according to the design of the first stage 22.

The sensing range of the first stage 22 is adjusted by the adjustment unit 23 and the adjustment value output by the adjustment 23 is determined by a dither signal. The adjustment value is P*LSB, wherein LSB indicates the smallest sensing voltage of the analog to digital converter 20, and N is integer number. For example, assuming the sensing range of the first stage 22 is from M*LSB to −M*LSB and the adjustment value is 1 LSB, the adjusted sensing range of the first stage 22 from (M−1)*LSB to −(M+1)*LSB. Furthermore, in FIG. 2, the sensing ranges of the first stage 22, the second stage 24, or the k^{th} stage 25 may be different, but the adjustment values for adjusting the sensing range thereof are the same.

The second stage 24 receives the second voltage V2 to generate a second digital code shown as B₂+r, and another voltage (not shown in FIG. 2). The k^{th} stage 25 generates the k^{th} digital code shown as Bₖ+r, but the k^{th} stage 25 does not output another voltage. The delay unit 26 receives the digital codes from the stages and output them at the same time. Assuming the processing time of one stage is T, the delay unit 26 delays the first digital code for (k−1)T, the second digital code for (k−2)T, and so on. The delay unit 26 combines the received digital codes to generate and transmit a C-bits digital code to the digital error correction logic 27. The digital error correction logic 27 removes the comparator offset error from the C-bits digital code to generate an N-bits digital code which corresponds the input voltage Vin.

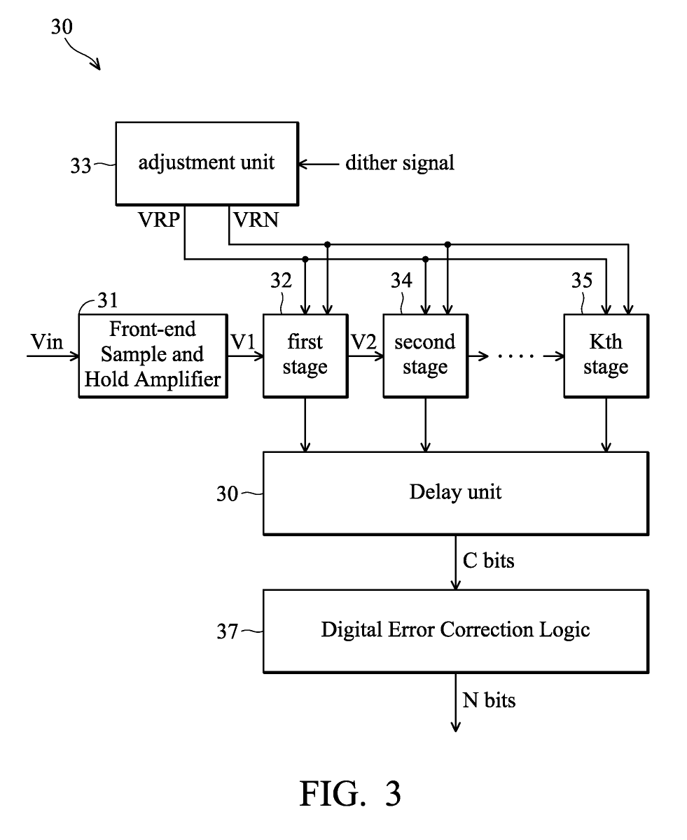

FIG. 3 is a block diagram of another embodiment of an analog to digital converter according to the invention. The analog to digital converter 30 comprises a front-end sample and hold amplifier 31, a first stage 32, an adjustment unit 33, a second stage 34, a k^{th} stage 35, a delay unit 36 and a digital error correction logic 37. In this embodiment, the operation of each stage, such as the first stage 32, the second stage 34, or k^{th} stage 35, is substantially the same, and the last stage, the k^{th} stage 35, is a flash analog to digital converter.

By utilizing the adjustment unit 33, the linearity of the analog to digital converter 30 can be improved. The adjustment unit 33 outputs two voltages, VRN and VRP, to be served as the upper threshold voltage and the bottom threshold voltage of the sensing range of each stage. In FIG. 3, the sensing ranges of the first stage 32, the second stage 34, or the k^{th} stage 35 are adjusted by the same adjustment voltage, however, the invention is not limited thereto. Those, skilled in the art may use a plurality of adjustment units to adjust the sensing range of each stage by different adjustment values, and the linearity of the analog to digital converter 30 can be improved more efficiently.

The front-end sample and hold amplifier 31 receives, samples and amplifies the input voltage Vin to generate a first voltage V1. It is noted that the front-end sample and hold amplifier 31 may not amplify the voltage Vin, and only sample the input voltage Vin, and the amplitude of the input voltage Vin is the same as the first voltage V1. The first stage 32 receives the first voltage V1 to generate a second voltage V2 and a first digital code. The first digital code is shown as B₁+r, wherein r indicates the error part or redundant part of the analog-to-digital conversion. In this embodiment, B₁ may be one bit value or a plurality of bit values according to the design of the first stage 32.

The sensing range of the first stage 32 is also adjusted by the adjustment unit 33 and the adjustment voltage output by the adjustment 33 is determined by a dither signal. The adjustment voltage is P*Vs, wherein Vs indicates the smallest sensing voltage of the analog to digital converter 30, and N is integer number. For example, assuming the sensing range of the first stage 32 is from 5V to −5V and the adjustment voltage is 0.005V, the adjusted sensing range of the first stage 32 from 4.995V to −4.995V. Furthermore, in FIG. 3, the sensing ranges of the first stage 32, the second stage 34, or the k^{th} stage 35 may be different, but the adjustment voltages for adjusting the sensing ranges thereof are the same.

The second stage 24 receives the second voltage V2 to generate a second digital code shown as B₂+r, and another voltage (not shown in FIG. 3). The k^{th} stage 35 generates the k^{th} digital code shown as Bₖ+r, but the k^{th} stage 35 does not output another voltage. The delay unit 36 receives the digital codes from the stages and output them at the same time. Assuming the processing time of one stage is T, the delay unit 36 delays the first digital code for (k−1)T, the second digital code for (k−2)T, and so on. The delay unit 36 combines the received digital codes to generate and transmit a C-bits digital code to the digital error correction logic 37. The digital error correction logic 37 removes the comparator offset error from the C-bits digital code to generate an N-bits digital code which corresponds the input voltage Vin.

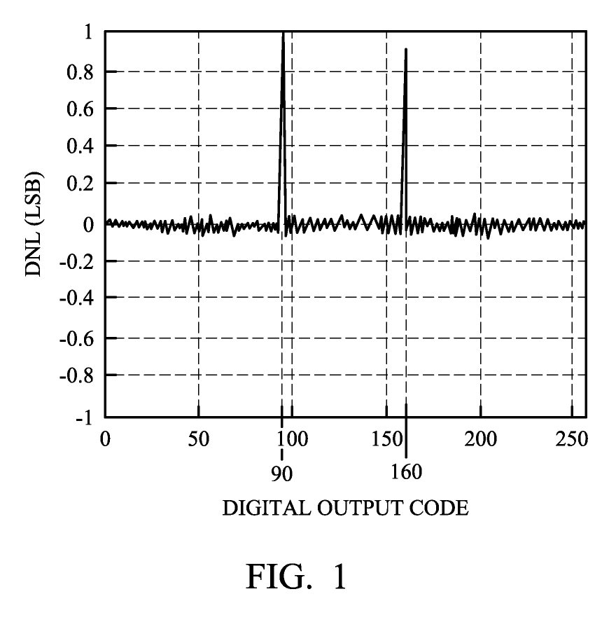

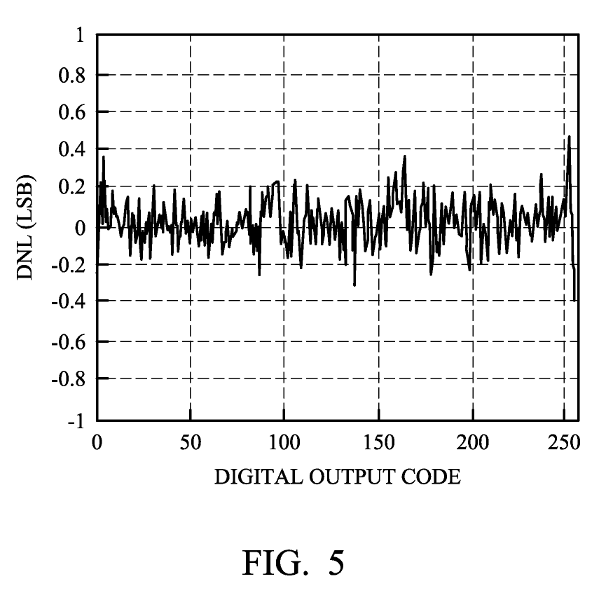

Please refer to FIG. 5. FIG. 5 is a schematic diagram showing the distribution of the DNL values of an embodiment of an analog to digital converter according to the invention. Compared with FIG. 1, it is shown that the DNL peaks have been eliminated. By adding a dither voltage, the DNL values can be normally distributed, and accordingly the performance and the linearity of the analog to digital converter can be improved. Furthermore, the converted digital value corresponding to the input voltage Vin can be more accurate.

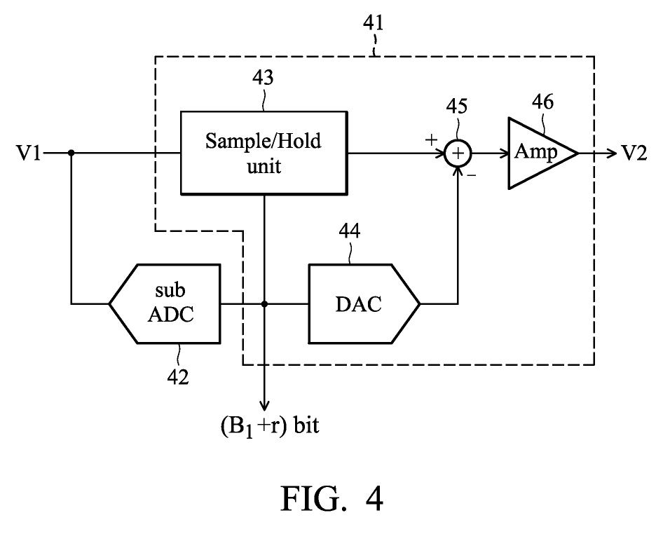

FIG. 4 is a block diagram of an embodiment of the first stage in FIG. 2 according to the invention. It is noted that the other stages may also have the same architecture of FIG. 4. The first stage 22 comprises a multiplying digital-to-analog converter (MDAC) 41 and a sub analog-to-digital converter (ADC) 42. The sub ADC 42 receives the first voltage V1 and generates the first digital code. It is noted that the conversion by the sub ADC may cause comparator offset error, but the error can be removed by the digital error correction logic 27.

The MDAC 41 receives the first voltage V1 and generates the second voltage V2 according to the first digital code. The MDAC 41 comprises a sample and hold unit 43 to hold the first voltage V1 for a predetermined time. The digital to analog converter (DAC) 44 generates voltage V1′ according to the first digital code. The subtractor 45 subtracts the voltage V1′ from the first voltage to generate a voltage difference, Vd. The amplifier 46 then amplifies the voltage difference to generate the second voltage V2. In one embodiment, the gain of the amplifier 46 is determined according the number of the bits of the first digital code. For example, if the first digital code comprises two bits, the gain of the amplifier 46 is also 2.

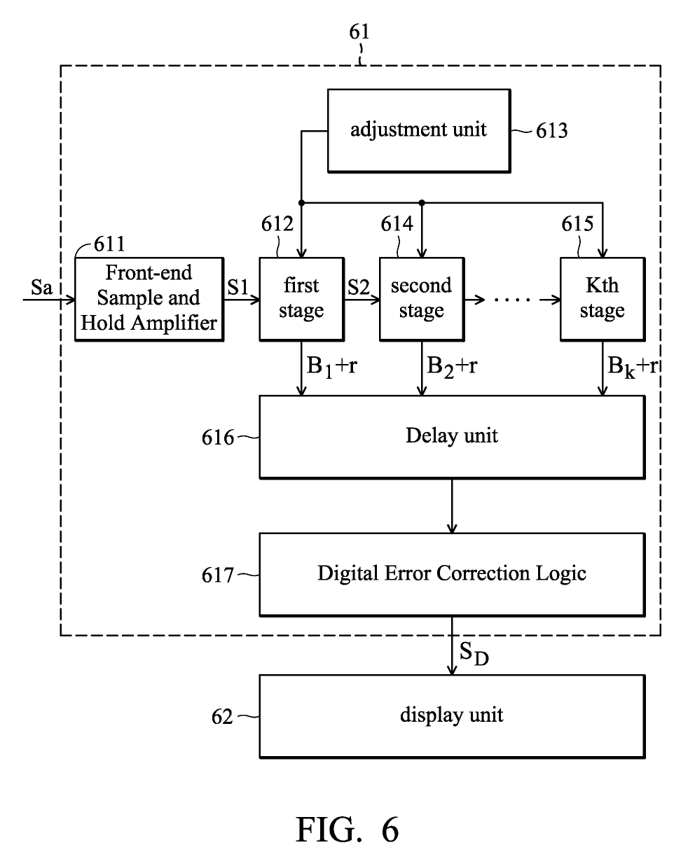

FIG. 6 is a schematic diagram of an embodiment of a video device according to the invention. The analog to digital converter 61 converts an analog signal Sₐ to generate a digital signal S_{D}. The display unit 62 receives the digital signal S_{D} to show a corresponding image. The analog to digital converter 61 comprises a front-end sample and hold amplifier 611, a first stage 612, an adjustment unit 613, a second stage 614, a k^{th} stage 615, a delay unit 616 and a digital error correction logic 617. In this embodiment, the operation of each stage, such as the first stage 612, the second stage 614, or k^{th} stage 615, is substantially the same, and the last stage, the k^{th} stage 615, is a flash analog to digital converter.

By utilizing the adjustment unit 613, the linearity of the analog to digital converter 61 can be improved. In FIG. 6, the sensing ranges of the first stage 612, the second stage 614, or the k^{th} stage 615 are adjusted by the same adjustment value, however, the invention is not limited thereto. Those skilled in the art may adjust each stage by different adjustment values, and the linearity of the analog to digital converter 61 can be improved more efficiently.

The front-end sample and hold amplifier 611 receives, samples and amplifies the input analog signal Sₐ to generate a first analog signal S1. It is noted that the front-end sample and hold amplifier 611 may not amplify the input analog signal Sₐ, and only sample the input analog signal Sₐ, and the amplitude of the input analog signal Sₐ is the same as the first analog signal S1. The first stage 612 receives the first analog signal S1 to generate a second analog signal S2 and a first digital signal. The first digital signal is shown as B₁+r, wherein r indicates the error part or redundant part of the analog-to-digital conversion. In this embodiment, B₁ may be one bit signal or a plurality of bit signals according to the design of the first stage 612.

The sensing range of the first stage 612 is adjusted by the adjustment unit 613 and the adjustment value output by the adjustment 613 is determined by a dither signal. The adjustment value is P*LSB, wherein LSB indicates the smallest sensing voltage of the analog to digital converter 61, and N is integer number. For example, assuming the sensing range of the first stage 612 is from M*LSB to −M*LSB and the adjustment value is 1 LSB, the adjusted sensing range of the first stage 612 from (M−1)*LSB to −(M+1)*LSB. Furthermore, in FIG. 6, the sensing ranges of the first stage 612, the second stage 614, or the k^{th} stage 615 may be different, but the adjustment values for adjusting the sensing range thereof are the same.

The second stage 614 receives the second analog signal S2 to generate a second digital signal shown as B₂+r, and another analog signal (not shown in FIG. 2). The k^{th} stage 615 generates the k^{th} digital signal shown as Bₖ+r, but the k^{th} stage 615 does not output another analog signal. The delay unit 616 receives the digital signals from the stages and output them at the same time. Assuming the processing time of one stage is T, the delay unit 616 delays the first digital signal for (k−1)T, the second digital signal for (k−2)T, and so on. The delay unit 616 combines the received digital signals to generate and transmit a C-bits digital signal to the digital error correction logic 617. The digital error correction logic 617 removes the comparator offset error from the C-bits digital signal to generate an N-bits digital signal, S_{D}, which corresponds the input analog signal Sₐ.

It is noted that the analog to digital converter 61 is illustrated with the analog to digital converter shown in FIG. 2, however, the invention is not limited thereto. The analog to digital converter 61 can also use the analog to digital converter shown in FIG. 3.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An analog to digital converter, comprising:
a first stage with a first sensing range to receive a first voltage to generate a first digital code;
an adjustment unit to adjust the first sensing range of the first stage; and
a digital error correction logic to receive and correct the first digital code to generate a digital code corresponding to the first voltage.

2. The converter as claimed in claim 1, wherein the first stage further outputs a second voltage, and the converter further comprises:
a second stage with a second sensing range to receive the second voltage to generate a second digital code, and the digital error correction logic receives and corrects the first digital code and the second digital code to generate the digital code corresponding to the first voltage.

3. The converter as claimed in claim 2, further comprising:
a delay unit to receive and delay the first digital code for a preset time period, and transmit the first digital code and the second digital code to the digital error correction logic after receiving the second digital code.

4. The converter as claimed in claim 3, wherein the preset time period is determined based on a generation time of the second digital code of the second stage.

5. The converter as claimed in claim 1, further comprising:
a front-end sample and hold amplifier to receive and amply an input voltage to generate the first voltage.

6. The converter as claimed in claim 1, wherein the first sensing range is increased or decreased by a predetermined value.

7. The converter as claimed in claim 6, wherein the predetermined value is one LSB.

8. The converter as claimed in claim 6, wherein the predetermined value is one sensing voltage level which is the smallest sensing voltage of the analog to digital converter.

9. The converter as claimed in claim 2, wherein the first sensing range and the second sensing range are increased or decreased by a predetermined value.

10. The converter as claimed in claim 9, wherein the predetermined value is one LSB.

11. The converter as claimed in claim 9, wherein the predetermined value is one sensing voltage level which is the smallest sensing voltage of the analog to digital converter.

12. The converter as claimed in claim 1, wherein the first stage comprising:
a sub analog to digital convert receiving the first voltage to generate the first digital code; and
a multiplying digital to analog converter to generate the second voltage.

13. The converter as claimed in claim 12, wherein the multiplying digital to analog converter further comprises:
a sub digital to analog converter receiving the first digital code to generate a fourth voltage;
a sample and hold unit to receive and output the first voltage;
a subtractor to subtract the fourth voltage from the first voltage to generate a voltage difference; and
an amplifier to amply the voltage difference to generate the second voltage.

14. A video device, comprising:
an analog to digital converter to convert a first analog signal to a digital signal, comprising:
a first stage with a first sensing range to receive a first analog signal to generate a first digital signal;
an adjustment unit to adjust the first sensing range of the first stage; and
a digital error correction logic to receive and correct the first digital signal to generate the digital signal corresponding to the first voltage; and
a display unit receiving the digital signal to show a corresponding image.

15. The device as claimed in claim 14, wherein the first stage further outputs a second analog signal, and the converter further comprises:
a second stage with a second sensing range to receive the second analog signal to generate a second digital signal, and the digital error correction logic receives and corrects the first digital signal and the second digital signal to generate the digital signal corresponding to the first voltage.

16. The device as claimed in claim 15, further comprising:
a delay unit to receive and delay the first digital signal for a preset time period, and transmit the first digital signal and the second digital signal to the digital error correction logic after receiving the second digital signal.

17. The device as claimed in claim 16, wherein the preset time period is determined based on a generation time of the second digital signal of the second stage.

18. The device as claimed in claim 15, further comprising:
a front-end sample and hold amplifier to receive and amply an input analog signal to generate the first analog signal.

19. The device as claimed in claim 15, wherein the first sensing range is increased or decreased by a predetermined value.

20. The device as claimed in claim 19, wherein the predetermined value is one LSB.

21. The device as claimed in claim 19, wherein the predetermined value is one sensing voltage level which is the smallest sensing voltage of the analog to digital converter.

22. The device as claimed in claim 15, wherein the first sensing range and the second sensing range are increased or decreased by a predetermined value.

23. The device as claimed in claim 22, wherein the predetermined value is one LSB.

24. The device as claimed in claim 22, wherein the predetermined value is one sensing voltage level which is the smallest sensing voltage of the analog to digital converter.

25. The device as claimed in claim 14, wherein the first stage comprising:
a sub analog to digital convert receiving the first analog signal to generate the first digital signal; and
a multiplying digital to analog converter to generate the second analog signal.

26. The device as claimed in claim 25, wherein the multiplying digital to analog converter further comprises:
a sub digital to analog converter receiving the first digital signal to generate a fourth analog signal;
a sample and hold unit to receive and output the first analog signal;
a subtractor to subtract the fourth analog signal from the first analog signal to generate a fifth analog signal; and
an amplifier to amply the fifth analog signal to generate the second analog signal.
